(19) United States
(12) Patent Application Publication
(10) Pub. No.: US 2019/0386679 A1
(43) Pub. Date: Dec. 19, 2019

(54) FLOATING POINT DATA COMPRESSION/COMPRESSOR

(71) Applicant: KONINKLIJKE PHILIPS N.V., EINDHOVEN (NL)

(72) Inventor: Kuldeep SINGH, PLEASANTON, CA (US)

(21) Appl. No.: 16/465,047

(22) PCT Filed: Nov. 22, 2017
(86) PCT No.: PCT/EP2017/080119

§ 371 Date: May 29, 2019

Related U.S. Application Data
(60) Provisional application No. 62/427,168, filed on Nov. 29, 2016.

(51) Int. Cl. H03M 7/30; G06F 7/483; H03M 7/24

(52) U.S. Cl. CPC H03M 7/30; H03M 7/24; G06F 7/483

(57) ABSTRACT

A computer-implemented method includes reading at least two thirty two-bit floating point values, converting the at least two floating point values to at least two thirty two-bit unsigned integer values, and storing the at least two unsigned integer values serially in a memory location of a memory device. The computer-implemented method further includes parsing each of the at least two unsigned integer values into four bytes, and rearranging first bytes of the at least two unsigned integer values in series in a first memory location, second bytes of the at least two unsigned integer values in series in a second memory location, third bytes of the at least two unsigned integer values in series in a third memory location, and fourth bytes of the at least two unsigned integer values in series in a fourth memory location. The computer-implemented method further includes compressing the rearranged bytes.

### FIELD OF THE INVENTION

The following generally relates to compressing floating point data and more particularly to a near-lossless floating point data compression/compressor, and is described with particular application to three-dimensional (3-D) dose data, e.g., for Intensity Modulated Proton Therapy (IMPT), Volumetric Modulated Arc Treatment (VMAT), and the like; however, the following is also amenable to other floating point data.

### BACKGROUND OF THE INVENTION

Treatment planning techniques such as IMPT and VMAT require dose be computed multiple times for a beam. With IMPT, dose is computed for each spot. With VMAT, dose is computed for each control point. As both of these techniques require inverse planning, there is a need to keep the complete computed dose in memory. Depending on the plan parameters, the total memory size of a plan can be multiple gigabytes (GB). For example, an IMPT plan may require 100 GB for dose data. The literature discusses approaches for reducing memory requirements, including reducing the dose grid resolution (which compromises quality), reducing the number of spots, and compressing the dose data.

Conceptually, compression algorithms are based on finding redundancy in the input data. For example, with IEEE floating point numbers, floating point data is separated into equivalent exponent and mantissa (significand), and then redundancies are identified in the mantissa and exponent data. However, the binary representation of two seemingly equal floating point numbers can be very different. Other approaches involve predicting the value and storing the difference, or by applying a masking strategy. Even though these approaches provide compression and no loss of data, the compression may not be enough for IMPT, VMAT, and/or other applications requiring storage of large amounts of floating point data.

### SUMMARY OF THE INVENTION

Aspects described herein address the above-referenced problems and others.

In one aspect, a computer-implemented method includes reading at least two thirty two-bit floating point values, converting the at least two floating point values to at least two thirty two-bit unsigned integer values, and storing the at least two unsigned integer values serially in a memory location of a memory device. The computer-implemented method further includes parsing each of the at least two unsigned integer values into four bytes, and rearranging first bytes of the at least two unsigned integer values in series in a first memory location, second bytes of the at least two unsigned integer values in series in a second memory location, third bytes of the at least two unsigned integer values in series in a third memory location, and fourth bytes of the at least two unsigned integer values in series in a fourth memory location. The computer-implemented method further includes compressing the rearranged bytes.

In another aspect, an apparatus includes a memory configured to store computer executable instructions and a processor configured to execute the computer executable instructions. The computer executable instructions cause the processor to: read at least two thirty two-bit floating point values from a memory device; convert the at least two floating point values to at least two thirty two-bit unsigned integer values, and store the at least two unsigned integer values serially in a memory location of the memory device. The computer executable instructions cause the processor to: parse each of the at least two unsigned integer values into four bytes, and rearrange first bytes of the at least two unsigned integer values in series in a first memory location, second bytes of the at least two unsigned integer values in series in a second memory location, third bytes of the at least two unsigned integer values in series in a third memory location, and fourth bytes of the at least two unsigned integer values in series in a fourth memory location. The computer executable instructions cause the processor to: compress the rearranged bytes.

In another aspect, a computer readable medium is encoded with computer executable instructions, which, in response to being executed by a processor of a computer, cause the computer to: read at least two thirty two-bit floating point values from a memory device, convert the at least two floating point values to at least two thirty two-bit unsigned integer values, and store the at least two unsigned integer values serially in a memory location of the memory device. The computer executable instructions further cause the computer to: parse each of the at least two unsigned integer values into four bytes, and rearrange first bytes of the at least two unsigned integer values in series in a first memory location, second bytes of the at least two unsigned integer values in series in a second memory location, third bytes of the at least two unsigned integer values in series in a third memory location, and fourth bytes of the at least two unsigned integer values in series in a fourth memory location. The computer executable instructions further cause the computer to: compress the rearranged bytes.

### BRIEF DESCRIPTION OF THE DRAWINGS

The invention may take form in various components and arrangements of components, and in various steps and arrangements of steps. The drawings are only for purposes of illustrating the preferred embodiments and are not to be construed as limiting the invention.

FIG. 1 schematically illustrates a computing system with a floating point value compressor/decompressor.

FIG. 2 schematically illustrates the computing system as part of an operator console of a radiation treatment system.

FIG. 3 schematically illustrates the computing system as a separate device in connection the radiation treatment system.

FIG. 4 illustrates an example computer-implemented method for compressing floating point values.

FIG. 5 illustrates an example computer-implemented method for decompressing floating point values.

### DETAILED DESCRIPTION OF EMBODIMENTS

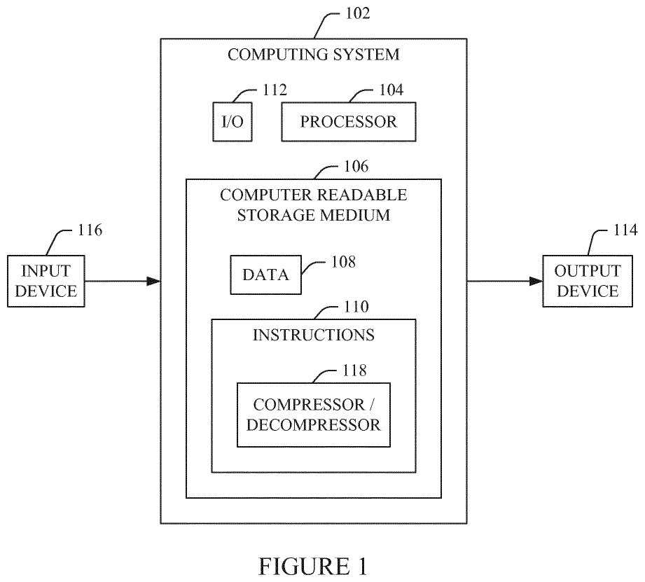

FIG. 1 schematically illustrates a computing system 102. The computing system 102 includes at least one processor 104 (e.g., a central processing unit or CPU, a microprocessor, a controller, or the like) and a computer readable storage medium 106 (which excludes transitory medium), such as physical memory and/or other non-transitory memory. The computer readable storage medium 106 stores data 108 and computer executable instructions (“instructions”) 110, which are executable by the at least one processor 104. The computing system 102 further includes input/output (I/O) 112, at least one output device 114 such as a display monitor, a printer, another computing device, etc. and at least one input device 116 such as a mouse, keyboard, another computing device, etc.

The computer executable instructions 110 include at least a compressor/decompressor module 120, which, when executed by the at least one processor 104, causes the at least one processor 104 to compress floating point data and/or causes the at least one processor 104 to decompress compressed floating point data. As described in greater detail below, the compression algorithm provides near-lossless compression with an accuracy on an order of 1e-6 (0.000001) and with a compression of up to 60% or more. The compressor/decompressor module 120 can be employed with any application, which uses floating point data.

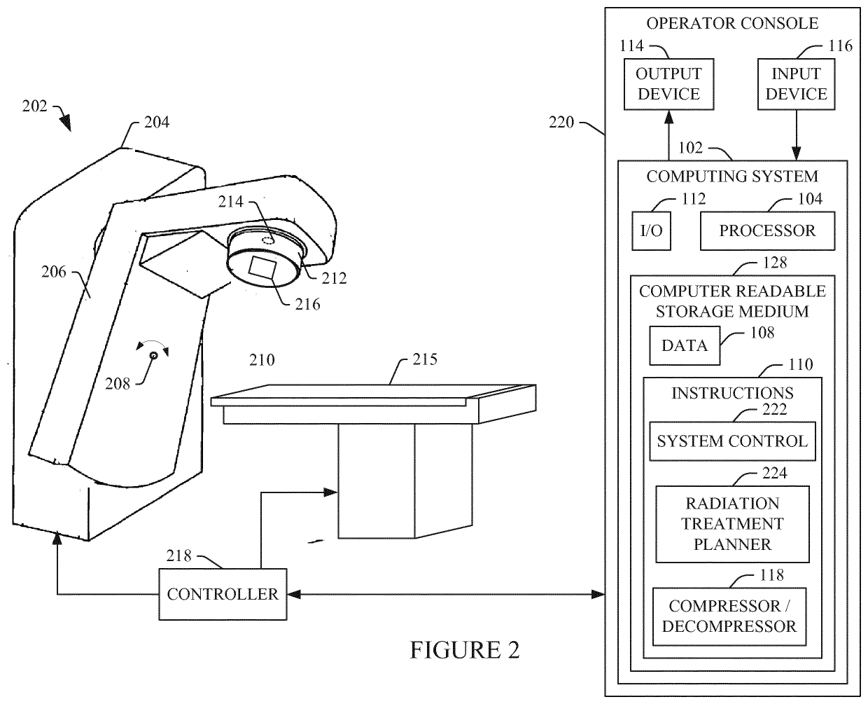

The computing system 102 can be employed with a radiation therapy (RT) system 202, such a linear accelerator, or linac, a proton therapy (PT) system such as a cyclotron, and/or other therapy system. For sake of brevity, FIG. 2 schematically illustrates an example in which the computing system 102 is employed with a radiation therapy system 202. The radiation therapy system 202 includes a stationary gantry 204 and a rotating gantry 206, which is rotatably attached to the stationary gantry 204. The rotating gantry 206 rotates (e.g., 180°, etc.) with respect to a rotation axis 208 about a treatment region 210.

A subject support 215 supports a portion of a subject in the treatment region 210. The rotating gantry 206 includes a treatment head 212 with a therapy (e.g., a megavolt (MV) radiation source 214 that delivers treatment radiation and a collimator 216 (e.g., a multi-leaf collimator) that can shape the radiation fields that exit the treatment head 212 into arbitrary shapes. The radiation source 214 rotates in coordination with the rotating gantry 206 about the treatment region 210. The collimator 216 includes a set of jaws that can move independently to shape a field.

A controller 218 is configured to control rotation of the rotating gantry 206 and deliver of treatment radiation by the megavolt radiation source 214 during a treatment such as an IMRT treatment, a VMAT treatment, and/or other radiation treatment. The controller 124 is also configured to control the system 202 for one or more other modes such as step and shoot delivery at a set of beam positions, combined volumetric arc and step-and-shoot delivery and one or more co-planar or non-coplanar arc deliveries.

The radiation therapy system 202 includes an operator console 220, which includes the computer system 102 with a radiation treatment control module (system control) 222 and a radiation treatment planner module 224 in the computer executable instructions 110. The radiation treatment control module 224 controls the controller 218, and the radiation treatment planner 224 creates radiation treatment plans. This includes IMRT, VMAT, etc. treatment plans, including dose.

In this example, the dose data for the IMRT, VMAT, etc. plans is stored in memory as floating point numbers. In this instance, the compressor/decompressor module 120, when executed by the at least one processor 104, causes the at least one processor 104 to compress, using the computer readable storage medium 106, the floating point dose data with a near-lossless compression, having an accuracy on an order of 1e-6. In one instance, the compressor/decompressor module 120 provides a memory savings, e.g., of up of 60% or higher, relative to a configuration in which the compression algorithm is not employed.

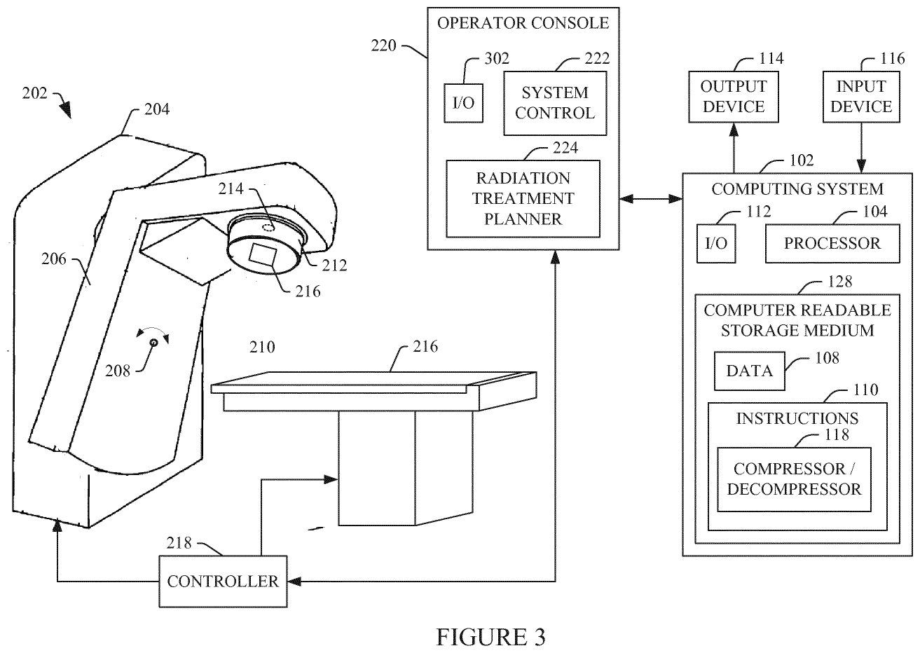

FIG. 3 schematically illustrates an example in which the operator console 220 does not include the computing system 102. In this example, the operator console 220 and the computing system 102 communicate via the I/O 122 and complementary I/O 302 of the operator console 220. Similar to FIG. 2, the compressor/decompressor module 120, when executed by the at least one processor 104, causes the at least one processor 104 to compress, using the computer readable storage medium 106, the floating point dose data with a near-lossless compression, having an accuracy on an order of 1e-6, which, in one instance, provides a memory saving, e.g., of up of 60% or higher, relative to a configuration in which the compression algorithm is not employed.

With continuing reference to FIGS. 1-3, an example of a suitable compression algorithm of the compressor/decompressor module 120 is described now. The compressor/decompressor module 120 converts floating point data to unsigned integer form and then stores the values by rearranging the bytes to achieve a maximum spatial redundancy. For conversion from a floating point value to an integer value, the floating point value is multiplied by 1e6 and then converted to an unsigned integer. As a result, the first six decimal digits are preserved. During decompression, for conversion from integer to floating point, the integer value is divided by 1e6. Where the conversion will cause an overflow, the floating point value is not converted, but instead saved along with a delimiter.

For IMPT, IMRT and VMAT plans, the total beam dose is computed by adding respectively the dose from individual spot and control points. As both of these techniques require inverse planning, there is a need to keep the complete computed dose in memory. With dose data stored in a single precision floating point three-dimensional (3-D) array, floating point operations (e.g., addition, division, etc.) are not associative, and values can only be computed with a predictable accuracy of ˜7.2 decimal digits, which roughly translates to accuracy of 1e-6. Certain lower values, such as those on an order of 1e-7 can be ignored since higher dose values are usually of more importance than lower values.

In a variation, a floating point value is converted to an integer value by multiplying by 1e-6, and the integer value is converted back to the floating point value by dividing by 1e-6.

In another variation, a floating point value and the integer value conversion is performed using a value other 1e-6, e.g., 1e-7, 1e-8, . . . , 1e-N, where N is an integer. In one instance, the value is predefined based on a predetermined accuracy. In another instance, the value is selectable from a plurality of predefined values, each based on a predetermined accuracy.

In another variation, values may be 16-bit, 64-bit, 128-bit, etc.

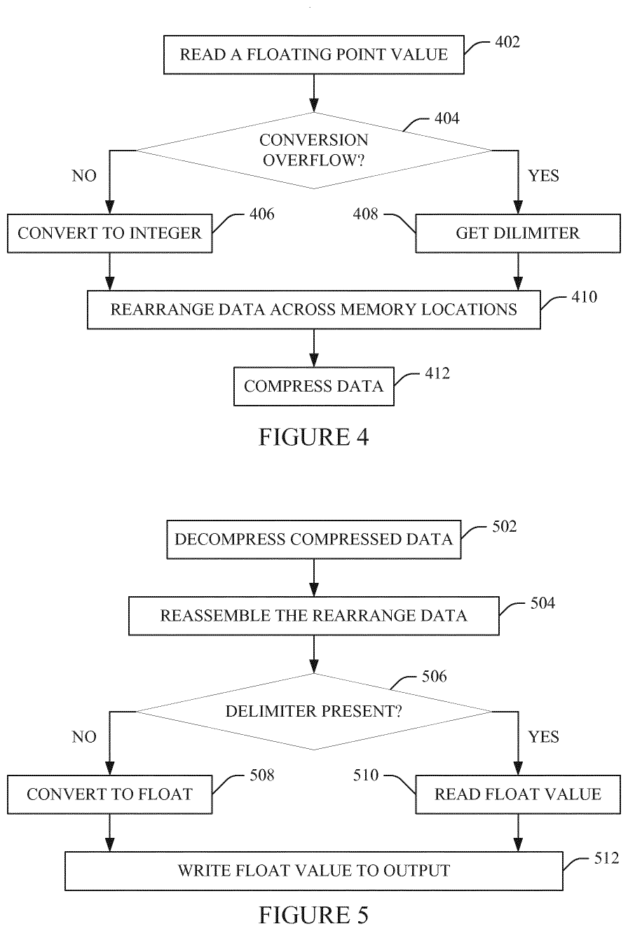

FIG. 4 schematically illustrates an example of the algorithm herein for compressing floating point data.

It is to be appreciated that the ordering of the acts in the method is not limiting. As such, other orderings are contemplated herein. In addition, one or more acts may be omitted and/or one or more additional acts may be included.

At 402, a floating point value is read from a memory device.

At 404, it is determined whether the conversion will result in an overflow.

If the conversion will not result in an overflow, then at 406, the floating point value is converted to an unsigned integer value.

If the conversion will result in an overflow, then at 408, the floating point value is not converted and an escape overflow delimiter is associated with the floating point value.

Alternatively, the floating point value is converted to the unsigned integer value, and the unsigned integer value is checked for an overflow condition.

At 410, integer values and floating point values with escape overflow delimiters are rearranged across memory locations in accordance with a predetermined pattern as described herein. This includes parsing the values into bytes and rearranging the bytes from a pattern in which all the bytes of a value are in contiguous memory locations and the values are stored serially, to a pattern where common bytes (e.g., the LSBs) of all of the values are instead in contiguous memory locations.

At 412, the rearranged values are compressed.

FIG. 5 schematically illustrates an example of the algorithm herein for decompressing floating point data.

It is to be appreciated that the ordering of the acts in the method is not limiting. As such, other orderings are contemplated herein. In addition, one or more acts may be omitted and/or one or more additional acts may be included.

At 502, the compressed data of act 412 of FIG. 4 is decompressed.

At 504, the rearranged data of act 410 of FIG. 4 are reassembled back to their pre-rearrangement configuration.

At 506, it is determined for reassembled data whether an escape overflow delimiter is present.

If the escape overflow delimiter is not present, then at 508 the integer data value is converted back to a floating point value.

If the escape overflow delimiter is present, then at 510 the floating point value is directly read.

At 512, the floating point values are output.

The acts herein may be implemented by way of computer readable instructions, encoded or embedded on computer readable storage medium, which, when executed by a computer processor(s), cause the processor(s) to carry out the described acts. Additionally, or alternatively, at least one of the computer readable instructions is carried by a signal, carrier wave or other transitory medium.

A numerical example is provided next. For this example, five floating point values are 1.2345678, 76.53428, 5000.003, 0.23367898 and 0.17027146. These values are converted to unsigned integer values by multiplying each by 1e6. The unsigned integer values are checked to see if they cause an overflow. In this example, the overflow unsigned integer delimiter 4294967295. As such, all of floating point values except 5000.003 do not cause an overflow. In a variation, the floating point values are checked to see if they cause an overflow by comparing them to a maximum float value of 4294.967.

Any unsigned integer value smaller than the overflow delimiter (or any float value equal to or smaller than the maximum float value) is stored in memory. For any unsigned integer value greater than or equal to the overflow delimiter (or any float value greater than the maximum float value), the original floating point value is stored in memory along with the overflow delimiter, which notifies the compressor/decompressor 118 to ignore the conversion of the value. This is shown below.

| Float | Integer | | |
|---|---|---|---|
| values | value | Binary Representation | Type |
| 1.2345678 | 123456 | 00000000000100101100111010110111 | (integer value) |
| 76.53428 | 76534280 | 00000100100011111101001000001000 | (integer value) |
| Delimiter | Delimiter | 11111111111111111111111111111111 | |
| 5000.003 | overflow | 01000101100111000100000000000110 | (float value) |
| 0.23367898 | 233678 | 00000000000000111001000011001110 | (integer value) |
| 0.17027146 | 1720271 | 00000000000000101001100100011111 | (integer value) |

The values are serially stored in memory. For example, the entire integer value 123456 is stored in consecutive bytes, the entire integer value 76534280 is then stored in consecutive bytes, the entire integer value of the delimiter 4294967295 is then stored in in consecutive bytes, the entire floating point value 5000.003 is then stored in consecutive bytes, the entire integer value 233678 is then stored in consecutive bytes, and the entire integer value 1720271 is then stored in consecutive bytes. An example of this is shown below.

| | C1 | C2 | C3 | C4 | C5 | C6 |
|---|---|---|---|---|---|---|
| R1 | 00000000 | 00010010 | 11001110 | 10110111 | 00000100 | 10001111 |
| R2 | 11010010 | 00001000 | 11111111 | 11111111 | 11111111 | 11111111 |
| R3 | 01000101 | 10011100 | 01000000 | 00000110 | 00000000 | 00000011 |
| R4 | 10010000 | 11001110 | 00000000 | 00000010 | 10011001 | 00011111 |

In this example, the integer value 123456 is stored in row 1 (R1), columns 1, 2, 3 and 4 (C1, C2, C3 and C4), the integer value 76534280 is stored in row 1, columns 5 and 6, and row 2 (R2), columns 1 and 2, the delimiter value is stored in row 2, columns 3-6, the floating point value 5000.003 is stored in row 3 (R3), columns 1-4, the integer value 233678 is stored in row 3 columns 5 and 6 and row 4 (R4), columns 1 and 2, and the integer value 1720271 is stored in row 4, columns 3-6.

In the above, the LSB's 10110111, 00001000, 11111111, 00000110, 11001110 and 00011111 are separated in memory by the other values. For example, the LSB 10110111 is at R1,C4, the LSB 00001000 is at R2,C2, the LSB 11111111 is at R2,C6, the LSB 00000110 is at R3,C4, the LSB 11001110 is at R4,C2, and the LSB 00011111 is at R4,C6. The other sets of bytes are also separated in memory. Each unsigned integer is rearranged by byte in memory so that the bytes of each set of bytes are in contiguous memory locations. This is shown below.

| | C1 | C2 | C3 | C4 | C5 | C6 |
|---|---|---|---|---|---|---|
| R1 | 00000000 | 00000100 | 11111111 | 01000101 | 00000000 | 00000000 |
| R2 | 00010010 | 10001111 | 11111111 | 10011100 | 00000011 | 00000010 |
| R3 | 11001110 | 11010010 | 11111111 | 01000000 | 10010000 | 10011001 |
| R4 | 10110111 | 00001000 | 11111111 | 00000110 | 11001110 | 00011111 |

In the above, the MSB's 00000000, 00000100, 11111111, 01000101, 00000000 and 00000000 are now all sequentially stored in column 1, . . . , and the LSB's 10110111, 00001000, 11111111, 00000110, 11001110 and 00011111 are now all sequentially stored in column 4. The rearranged data is then compressed. Row 1 will contain mostly zeroes and can be compressed with almost no storage. Examples of suitable compressor/decompressors include zlib, lzo or any other lossless data compressor/decompressors.

The decompression process is the reverse of the above compression process. The compressed data is decompressed. The decompressed data is reassembled back into 32-bit values stored in series. For 32-bit values not associated with the overflow delimiter, the unsigned integers are converted back to floating point values by dividing by 1e6. For 32-bit values associated with the overflow delimiter, the floating point values are read. All of the floating point values are then written to the output. The dose data can then be visually presented, printed, etc.

For comparative purposes, compression results for floating point data for an IMPT beam in a water phantom with 14553 spots and CT beams in a subject with 568 and 752 spots are shown below. Column 1 indicates the beam. Column 2 shows the uncompressed (UC) size in megabytes (MB). Columns 3, 4, 5 and 6 shows the size in megabytes (MB) respectively for compression using the zlib compressor after rearranging the data as described herein, and compression using zfp, pfzip and zlib are without rearranging the data as described herein. Columns 7, 8, 9 and 10 show corresponding compression ratios, which shows compression ratios of ˜57%, 52% and 62% for the approach described herein.

| | | Compressed Size (MB) | | | | Compression Ratio | | | |
|---|---|---|---|---|---|---|---|---|---|
| | UC Size | Rearrange + | | | | Rearrange + | | | |
| Plan | (MB) | zlib | zfp | fpzip | zlib | zlib | zfp | fpzip | zlib |
| Water | 13183.28 | 5772.033 | 8083.057 | 9835.569 | 12210.55 | 2.28 | 1.63 | 1.34 | 1.08 |
| Phantom | | | | | | | | | |
| CT | 390.18 | 186.281 | 229.084 | 293.562 | 364.664 | 2.09 | 1.7 | 1.33 | 1.07 |
| Beam 1 | | | | | | | | | |
| CT | 759.277 | 292.31 | 393.459 | 565.333 | 708.753 | 2.6 | 1.93 | 1.34 | 1.07 |
| Beam 2 | | | | | | | | | |

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A computer-implemented method, comprising:
reading at least two thirty two-bit floating point values;
converting the at least two floating point values to at least two thirty two-bit unsigned integer values;
storing the at least two unsigned integer values serially in a memory location of a memory device;
parsing each of the at least two unsigned integer values into four bytes;
rearranging first bytes of the at least two unsigned integer values in series in a first memory location, second bytes of the at least two unsigned integer values in series in a second memory location, third bytes of the at least two unsigned integer values in series in a third memory location, and fourth bytes of the at least two unsigned integer values in series in a fourth memory location; and
compressing the rearranged bytes.

2. The computer-implemented method of claim 1, further comprising:
decompressing the rearranged bytes;
reassembling the first, the second, the third and the fourth bytes of each of the at least two thirty two-bit unsigned integer values;
storing the reassembled at least two unsigned integer values serially in memory locations of the memory device; and
converting the at least two unsigned integer values back to the at least two thirty two-bit floating point values.

3. The computer-implemented method of claim 1, further comprising:
determining, prior to converting a first of the at least two floating point values to a first of the at least two thirty two-bit unsigned integer values, the conversion of the first of the at least two floating point values will not result in an overflow; and
converting the first of the at least two floating point values to the first of the at least two thirty two-bit unsigned integer values in response to the determination.

4. The computer-implemented method of claim 3, further comprising:
determining, prior to converting a second of the at least two floating point values to a second of the at least two thirty two-bit unsigned integer values, the conversion of the second of the at least two floating point values will result in an overflow;
terminating the conversion of the second of the at least two floating point values to the second of the at least two thirty two-bit unsigned integer values in response to the determination; and
storing a predetermined overflow delimiter value and the second of the at least two floating point values in series in the memory location in place of the second of the at least two thirty two-bit unsigned integer values.

5. The computer-implemented method of claim 4, wherein the parsing further includes parsing the predetermined overflow delimiter value and the second of the at least two floating point values each into four bytes, and the rearranging further includes:
rearranging first bytes of the predetermined overflow delimiter value and the second of the at least two floating point values with the other first bytes in the first memory location;
rearranging second bytes of the predetermined overflow delimiter value and the second of the at least two floating point values with the other second bytes in the second memory location,
rearranging third bytes of the predetermined overflow delimiter value and the second of the at least two floating point values with the other third bytes in the third memory location; and
rearranging fourth bytes of the predetermined overflow delimiter value and the second of the at least two floating point values with the other fourth bytes in the fourth memory location.

6. The computer-implemented method of claim 1, further comprising:
comparing, after converting the at least two floating point values to the at least two thirty two-bit unsigned integer values, a first of the at least two thirty two-bit unsigned integer values with a predetermined overflow delimiter value;
determining the conversion of the first of the at least two floating point values to the first of the two thirty two-bit unsigned integer values did not result in an overflow in response to the comparison; and
storing the first of the two thirty two-bit unsigned integer values in response to the determination.

7. The computer-implemented method of claim 6, further comprising:
comparing, after converting the at least two floating point values to the at least two thirty two-bit unsigned integer values, a second of the at least two thirty two-bit unsigned integer values with the predetermined overflow delimiter value;
determining the conversion of the second of the at least two floating point values to the second of the two thirty two-bit unsigned integer values results in an overflow in response to the comparison; and
storing the predetermined overflow delimiter value and the second of the at least two floating point values in series in the memory location and not the second of the two thirty two-bit unsigned integer values.

8. The computer-implemented method of claim 7, wherein the parsing further includes parsing the predetermined overflow delimiter value and the second of the at least two floating point values each into four bytes, and the rearranging further includes:
rearranging first bytes of the predetermined overflow delimiter value and the second of the at least two floating point values with the other first bytes in the first memory location;
rearranging second bytes of the predetermined overflow delimiter value and the second of the at least two floating point values with the other second bytes in the second memory location,
rearranging third bytes of the predetermined overflow delimiter value and the second of the at least two floating point values with the other third bytes in the third memory location; and
rearranging fourth bytes of the predetermined overflow delimiter value and the second of the at least two floating point values with the other fourth bytes in the fourth memory location.

9. The computer-implemented method of claim 5, further comprising:
decompressing the rearranged bytes;
reassembling the first, second, third and fourth bytes of each of the first of the unsigned integer value, the predetermined overflow delimiter value, and the second of the at least two floating point values in series;
converting the first of the unsigned integer value back to a floating point value;
reading the second of the at least two floating point values; and
writing both of the floating point values to memory.

10. The computer-implemented method of claim 1, wherein the at least two floating point values represent three-dimensional radiation dose data from at least one of an Intensity Modulated Proton Therapy plan or a Volumetric Modulated Arc Treatment plan.

11. An apparatus, comprising:
a memory configured to store computer executable instructions; and
a processor configured to execute the computer executable instructions, wherein the computer executable instructions cause the processor to:
read at least two thirty two-bit floating point values from a memory device;
convert the at least two floating point values to at least two thirty two-bit unsigned integer values;
store the at least two unsigned integer values serially in a memory location of the memory device;
parse each of the at least two unsigned integer values into four bytes;
rearrange first bytes of the at least two unsigned integer values in series in a first memory location, second bytes of the at least two unsigned integer values in series in a second memory location, third bytes of the at least two unsigned integer values in series in a third memory location, and fourth bytes of the at least two unsigned integer values in series in a fourth memory location; and
compress the rearranged bytes.

12. The apparatus of claim 11, wherein the computer executable instructions cause the processor to:
decompress the rearranged bytes;
reassemble the first, the second, the third and the fourth bytes of each of the at least two unsigned integer values;
store the reassembled at least two unsigned integer values serially in memory locations of the memory device; and
convert the at least two unsigned integer values back to the at least two floating point values.

13. The apparatus of claim 11, wherein the computer executable instructions cause the processor to:
determine, prior to converting a first of the at least two floating point values to a first of the at least two thirty two-bit unsigned integer values, the conversion of the first of the at least two floating point values will result in an overflow;
terminate the conversion of the first of the at least two floating point values to the first of the at least two thirty two-bit unsigned integer values in response to the determination; and
store a predetermined overflow delimiter value and the first of the at least two floating point values in series in the memory location in place of the first of the at least two thirty two-bit unsigned integer values.

14. The apparatus of claim 13, wherein the computer executable instructions cause the processor to:
parse the predetermined overflow delimiter value and the first of the at least two floating point values each into four bytes;
rearrange first bytes of the predetermined overflow delimiter value and the first of the at least two floating point values with the other first bytes in the first memory location;
rearrange second bytes of the predetermined overflow delimiter value and the first of the at least two floating point values with the other second bytes in the second memory location,
rearrange third bytes of the predetermined overflow delimiter value and the first of the at least two floating point values with the other third bytes in the third memory location; and
rearrange fourth bytes of the predetermined overflow delimiter value and the first of the at least two floating point values with the other fourth bytes in the fourth memory location.

15. The apparatus of claim 11, further comprising:
comparing, after converting the at least two floating point values to the at least two thirty two-bit unsigned integer values, a first of the at least two thirty two-bit unsigned integer values with a predetermined overflow delimiter value;
determining the conversion of the first of the at least two floating point values to the first of the two thirty two-bit unsigned integer values results in an overflow in response to the comparison; and
storing the predetermined overflow delimiter value and the first of the at least two floating point values in series in the memory location and not the first of the two thirty two-bit unsigned integer values.

16. The apparatus of claim 15, wherein the computer executable instructions cause the processor to:
parse the predetermined overflow delimiter value and the first of the at least two floating point values each into four bytes;
rearrange first bytes of the predetermined overflow delimiter value and the first of the at least two floating point values with the other first bytes in the first memory location;
rearrange second bytes of the predetermined overflow delimiter value and the first of the at least two floating point values with the other second bytes in the second memory location,
rearrange third bytes of the predetermined overflow delimiter value and the first of the at least two floating point values with the other third bytes in the third memory location; and
rearrange fourth bytes of the predetermined overflow delimiter value and the first of the at least two floating point values with the other fourth bytes in the fourth memory location.

17. The apparatus of claim 13, further comprising:
decompressing the rearranged bytes;
reassembling the first, second, third and fourth bytes of each of the first of the unsigned integer value, the predetermined overflow delimiter value, and the second of the at least two floating point values in series;
converting the first of the unsigned integer value back to a floating point value;
reading the second of the at least two floating point values; and
writing both of the floating point values to memory.

18. The apparatus of claim 11, wherein the at least two floating point values represent three-dimensional radiation dose data from at least one of an Intensity Modulated Proton Therapy plan or a Volumetric Modulated Arc Treatment plan.

19. A computer readable medium encoded with computer executable instructions, which, in response to being executed by a processor of a computer, cause the computer to:
read at least two thirty two-bit floating point values from a memory device;
convert the at least two floating point values to at least two thirty two-bit unsigned integer values;
store the at least two unsigned integer values serially in a memory location of the memory device;
parse each of the at least two unsigned integer values into four bytes;
rearrange first bytes of the at least two unsigned integer values in series in a first memory location, second bytes of the at least two unsigned integer values in series in a second memory location, third bytes of the at least two unsigned integer values in series in a third memory location, and fourth bytes of the at least two unsigned integer values in series in a fourth memory location; and
compress the rearranged bytes.

20. The computer readable medium of claim 19, wherein the computer executable instructions further cause the processor to:
decompress the rearranged bytes;
reassemble the first, second, third and fourth bytes of each of the at least two unsigned integer values;
store the reassembled at least two unsigned integer values serially in memory locations of the memory device; and
convert the at least two unsigned integer values back to at least two floating point values.
